(19) United States
(12) Patent Application Publication
(10) Pub. No.: US 2012/0139850 A1
(43) Pub. Date: Jun. 7, 2012

(54) HAPTIC DRIVING ASSEMBLY AND ELECTRONIC DEVICE USING THE SAME

(75) Inventors: Boum Seock KIM, Gyunggi-do (KR); Seung Gyo JEONG, Gyunggi-do (KR); Eun Tae PARK, Gyunggi-do (KR)

(73) Assignee: SAMSUNG ELECTRO-MECHANICS CO., LTD., Gyunggi-do (KR)

(21) Appl. No.: 13/153,896

(22) Filed: Jun. 6, 2011

(30) Foreign Application Priority Data
Dec. 7, 2010 (KR) 10-2010-0124470

(51) Int. Cl. G08B 6/00; H01L 41/04; G06F 3/041

(52) U.S. Cl. 345/173; 310/334; 340/407.2

(57) ABSTRACT

There is provided a haptic driving assembly capable of providing more uniform haptic feedback, and an electronic device using the same. The haptic driving assembly includes: at least one actuator; and a vibration transferring part disposed to contact at least one surface of the actuator and transferring vibrations generated in the actuator to the outside through a liquid phase medium.

### CROSS-REFERENCE TO RELATED APPLICATIONS

This application claims the priority of Korean Patent Application No. 10-2010-0124470 filed on Dec. 7, 2010, in the Korean Intellectual Property Office, the disclosure of which is incorporated herein by reference.

### BACKGROUND OF THE INVENTION

1. Field of the Invention

The present invention relates to a haptic driving assembly and an electronic device using the same, and more particularly, to a haptic driving assembly capable of providing uniform haptic feedback, and an electronic device using the same.

2. Description of the Related Art

In accordance with the recent demand by users for simplification in the usage of electronic devices, a touchscreen type device in which input is performed by touching the screen of an electronic device has generally been used.

Currently, a haptic feedback device includes the concept of reflecting intuitive user experience in an interface and further diversifying touch feedback, in addition to the concept of a user performing input by touching the electronic device.

Here, the haptic feedback device has various advantages, such as being easily compatible with IT devices, in addition to being able to be housed in a small space, having improved and simplified operability, ease in changing the specifications thereof, and high user recognition.

Due to these advantages, the haptic feedback device has been widely used in electronic devices used in home computers, traffic ticket issuing devices, public information services, medical equipment, mobile communications devices, or the like.

As an actuator for implementing a haptic function, a piezo-type actuator has recently been used, and of these, an actuator having a bar shape has mainly been used.

A plurality of bar-shaped actuators may be included in a single electronic device. Here, the plurality of actuators are generally disposed to be spaced apart from one another as distantly as possible. For example, when bar shaped actuators are included in a touchscreen display device, the respective actuators may be disposed along opposing edges of the touchscreen display device.

However, according to the related art described above, when the user touches a point of a touchscreen display device (for example, an edge portion of the touchscreen display device) close to the actuator, reaction speed is high, and vibration strength is also high. However, when the user touches a point of a touchscreen display device (for example, a center portion of the touchscreen display device) distant from the actuator, reaction speed is low, and vibration strength may also be low. That is, there may be a problem in that vibration sensitivity may not be uniform according to a touch position.

### SUMMARY OF THE INVENTION

An aspect of the present invention provides a haptic driving assembly capable of providing uniform haptic feedback, and an electronic device using the same.

According to an aspect of the present invention, there is provided a haptic driving assembly including: at least one actuator; and a vibration transferring part disposed to contact at least one surface of the actuator and transferring vibrations generated in the actuator to the outside through a liquid phase medium.

The vibration transferring part may include: a medium part formed of the liquid phase medium; and a protective cover enclosing an outer portion of the medium part and protecting the medium part.

The medium part may be formed of a liquid material having a specific gravity greater than that of water.

The protective cover may be formed of a film material having flexibility.

The actuator may be attached to an inner surface of the protective cover, such that all surfaces thereof except for a surface attached to the inner surface of the protective cover directly contact the medium part.

The vibration transferring part may include at least one groove having the actuator inserted thereinto and contacting thereto.

The actuator may be a piezo actuator having a bar shape.

The actuator may generate an ultrasonic wave through the vibrations to thereby transfer the ultrasonic wave to the vibration transferring part.

The vibration transferring part may have the medium part vibrated by the ultrasonic wave transferred from the actuator and transfer the vibrations to the outside.

According to another aspect of the present invention, there is provided an electronic device including: the haptic driving assembly as described above; and a display panel disposed to contact an outer portion of the vibration transferring part.

The display panel may include: an image displaying unit displaying an image; and a touch panel attached to an upper surface of the image displaying unit to thereby sense touch input from the outside.

The electronic device may further include a case receiving the haptic driving assembly and the display panel therein.

The electronic device may further include a buffering member fixedly coupled to a circumference of the support plate to thereby keep vibrations generated in the haptic driving assembly from being transferred to the case.

The electronic device may further include a support plate having the haptic driving assembly disposed between the support plate and the display panel to thereby support the haptic driving assembly.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is an exploded perspective view of a mobile communications terminal according to an exemplary embodiment of the present invention;

FIG. 2 is a perspective view showing a haptic driving assembly of the mobile communications terminal shown in FIG. 1;

FIG. 3 is a partial cross-sectional view of the mobile communications terminal shown in FIG. 1; and

FIG. 4 is a partial cross-sectional view of a mobile communications terminal according to another exemplary embodiment of the present invention.

### DETAILED DESCRIPTION OF THE PREFERRED EMBODIMENT

Prior to a detailed description of the present invention, the terms or words, which are used in the specification and claims to be described below, should not be construed as having typical or dictionary meanings. The terms or words should be construed in conformity with the technical idea of the present invention on the basis of the principle that the inventor(s) can appropriately define terms in order to describe his or her invention in the best way. Embodiments described in the specification and structures illustrated in drawings are merely exemplary embodiments of the present invention. Thus, it is intended that the present invention covers the modifications and variations of this invention, provided they fall within the scope of their equivalents at the time of filing this application.

Exemplary embodiments of the present invention will be described in detail with reference to the accompanying drawings. The same reference numerals will be used throughout to designate the same or like elements in the accompanying drawings. Moreover, detailed descriptions related to well-known functions or configurations will be ruled out in order not to unnecessarily obscure subject matters of the present invention. In the drawings, the shapes and dimensions of some elements may be exaggerated, omitted or schematically illustrated. Also, the size of each element does not entirely reflect an actual size.

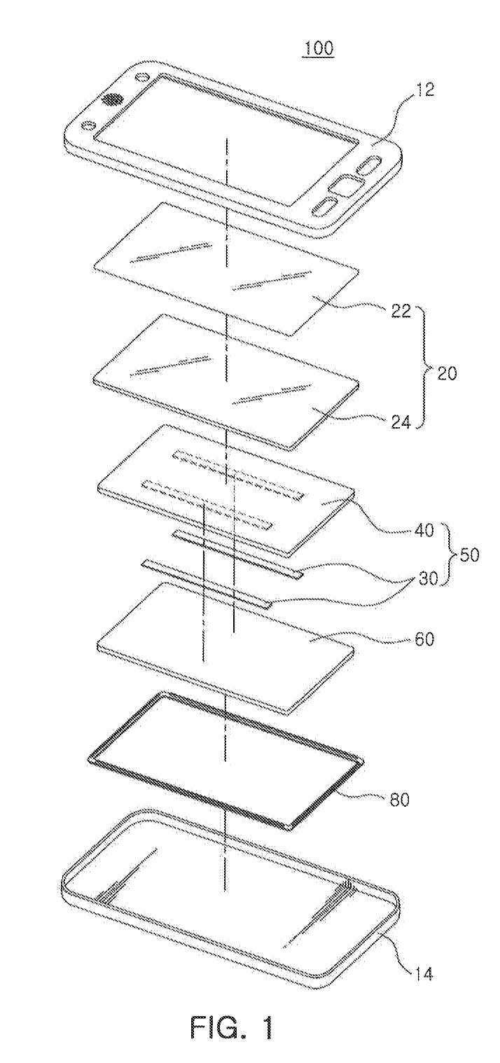

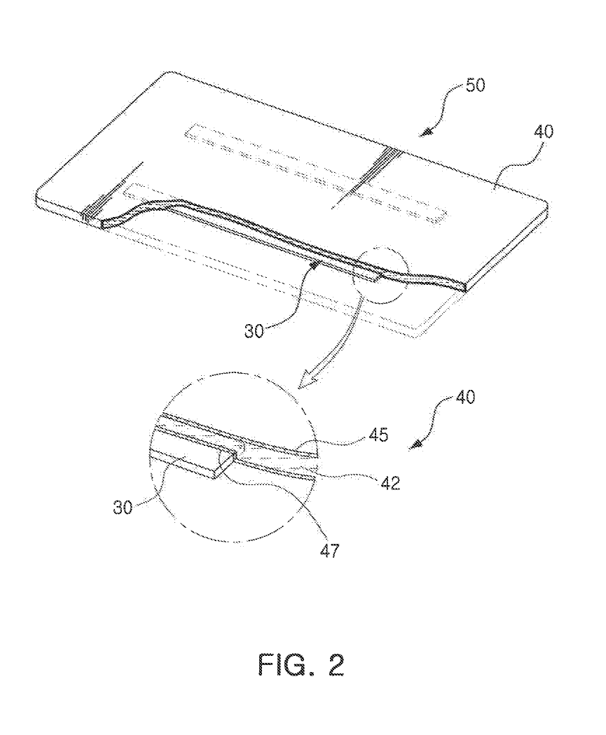

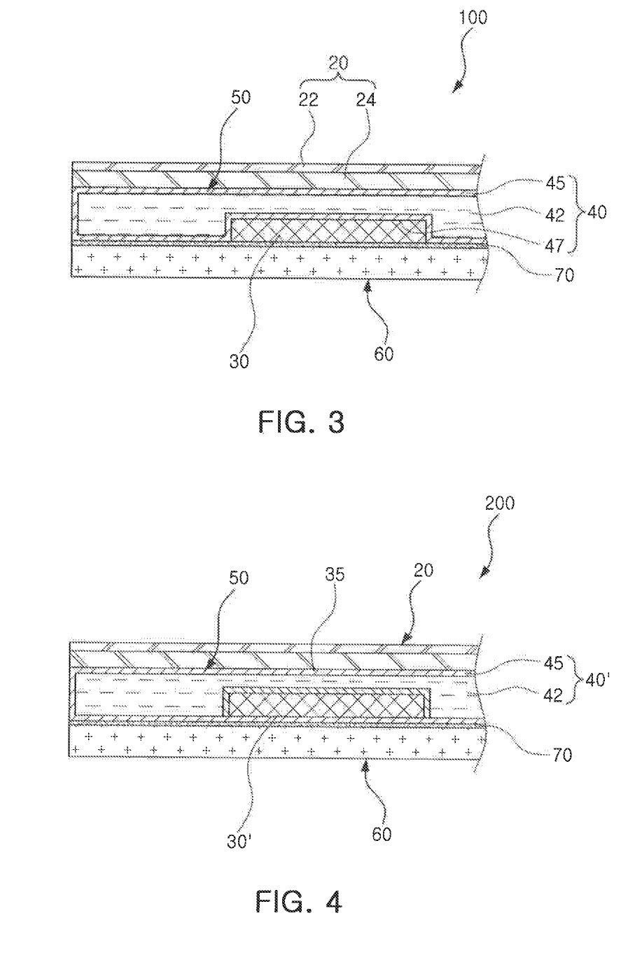

FIG. 1 is an exploded perspective view of a mobile communications terminal according to an exemplary embodiment of the present invention; FIG. 2 is a perspective view showing a haptic driving assembly of the mobile communications terminal shown in FIG. 1; and FIG. 3 is a partial cross-sectional view of the mobile communications terminal shown in FIG. 1.

Hereinafter, an electronic device according to an exemplary embodiment of the present invention will be described using an example of a mobile communications terminal 100. However, the present invention is not limited thereto but may be applied to all of haptic devices in which feedback is generated according to contact by a user, such as various office automation (OA) devices, medical devices, mobile communication devices, traffic ticket issuing devices, or the like.

Referring to FIG. 1, the mobile communications terminal 100, which is the electronic device according to the exemplary embodiment of the present invention, may include a case 12 and 14, a display panel 20, a haptic driving assembly 50, and a support plate 60.

The case 12 and 14 may be configured of a front case 12 and a rear case 14, and the front case 12 and the rear case 14 may be combined with each other to form an internal space therebetween.

The display panel 20 may display an image of the mobile communications terminal 100 and include an image displaying unit 24 and a touch panel 22.

The image displaying unit 24 displays an image on a front surface of the mobile communications terminal 100 according to the controlling of a controller (not shown).

The image displaying unit 24 according to the present embodiment may be a liquid crystal display (LCD). In this case, the image displaying unit 24 may include a liquid crystal panel and a back light.

The liquid crystal panel controls the light transmissivity of liquid crystal cells injected between two glass substrates to thereby display an image. Each of the liquid crystal cells controls the amount of transmitted light in response to a video signal, that is, a corresponding pixel signal.

The back light irradiates the liquid crystal panel with light. Therefore, the user may identify a screen through the light transmitted through the liquid crystal panel.

Meanwhile, the image displaying unit 24 according to the present embodiment is not limited to a liquid crystal display (LCD) device. That is, in addition to the LCD, various flat panel display devices such as a plasma display panel (PDP), an electro luminance display (ELD), or the like, may be used. In addition, a device used as the image displaying unit may be easily alterable by those skilled in the art and understanding the spirit of the present invention.

The touch panel 22 is attached to an outer surface of the image displaying unit 24 and generates an input signal from a voltage signal or a current signal generated according to a position at which a touch is made thereon to transmit the input signal to the controller (not shown).

The touch panel 22 may include upper and lower substrates formed of an indium-tin-oxide (ITO) or polyethylene terephthalate (PET) film having an ITO electrode film formed therein, an electrode pattern formed on the electrode film, and a spacer maintaining an appropriate interval between the upper and lower substrates. In this case, the ITO electrode film has conductive X axial and Y axial patterns each formed at an edge thereof, and the X axial and Y axial patterns are separated from each other by an insulator.

Therefore, when the user presses the upper substrate of the touch panel 22 with his finger, or the like, the ITO electrode film on the upper substrate contacts the ITO electrode film on the lower substrate. Accordingly, voltages are read from the X and Y axial patterns to extract a coordinate of the pressed point and transfer the extracted coordinate to the controller.

When the touch input is made by the user, the display panel 20 according to the present embodiment provides feedback for the touch input, while displaying the image to the user. Here, the feedback is provided through vibrations, which are provided by the haptic driving assembly 50 described below.

The haptic driving assembly 50 is disposed on a lower portion of the display panel 20 and vibrates the display panel 20 when the touch input is made, thereby allowing the user to feel the feedback for the touch input.

To this end, the haptic driving assembly 50 according to the present embodiment is configured to include an actuator 30 generating vibrations and a vibration transferring part 40 uniformly transferring the vibrations generated by the actuator 30 to the outside.

The actuator 30 is formed as a piezo actuator or a polymer actuator and generates vibrations corresponding to touch input when the touch input is made on the display panel 20. Here, the actuator 30 may provide different kinds of vibrations to the user according to the contact time, pressure change, or the like, of the touch input, to thereby feedback various haptic sensations.

The actuator 30 has magnitude of vibrations (for example, strength of vibrations) and the number of vibrations (for example, vibrational number, vibrational frequency) determined by a control unit (not shown) included in a circuit board (not shown). That is, the control unit may change the magnitude and frequency of a voltage applied to the actuator 30 as needed to thereby change the magnitude and number of vibrations of the actuator 30.

The actuator 30 according to the present embodiment may be a ceramic laminate having an electrode interposed therebetween, wherein the electrode has a bar shape.

The vibration transferring part 40 transfers the vibrations generated in the actuator 30 to the display panel 20. To this end, the vibration transferring part 40 is configured of a medium part 42 transferring the vibrations and a protective cover 45 protecting the medium part 42.

The vibration transferring part 40 according to the present embodiment is characterized in that the medium part 42 is formed of a liquid phase medium.

When a specific gravity of the liquid phase medium composing the medium part 42 is significantly low, the vibrations generated in the actuator 30 may not be accurately transferred to the display panel 20. Therefore, the medium part 42 according to the present embodiment has a specific gravity greater than that of water.

As the medium part 42, oil, or the like, may be used; however, the present invention is not limited thereto.

The protective cover 45 should be capable of sealing the liquid phase medium so that the liquid phase medium is not leaked to the outside, while maximally transferring the vibrations transferred through the medium part 42 to the display panel 20. Therefore, as the protective cover 45 according to the present embodiment, a flexible and thin vinyl material may be used. More specifically, a film material having flexibility may be used. However, a material of the protective cover 45 is not limited thereto.

The vibration transferring part 40 having the above-mentioned configuration is interposed between the display panel 20 and the support plate 60 described below, and serves to transfer the vibrations generated in the actuator 30 to the display panel 20, as described above. Therefore, the vibration transferring part 40 should contact the actuator 30 and the display panel 20 so as to be closely adhered thereto in order to minimize loss in the transferred vibrations.

Therefore, the vibration transferring part 40 according to the present embodiment is formed to have an area corresponding to that of the display panel 20, and is formed to have a shape in which it fills a space formed between the display panel 20 and the support plate 60. Accordingly, an upper surface of the vibration transferring part 40 surface contacts a lower surface of the display panel 20, and a lower surface of the vibration transferring part 40 surface contacts an upper surface of the support plate 60.

In addition, the vibration transferring part 40 according to the present embodiment is formed to have a very thin thickness in order to secure vibration strength. That is, the vibration transferring part 40 may be formed to be as thin as possible in a range in which the upper surface of the actuator 30 does not contact the lower surface of the display panel 20 when the actuator 30 vibrates.

In addition, the vibration transferring part 40 according to the present embodiment surface contacts at least one surface (for example, an upper surface) of the actuator 30 to thereby be coupled to the actuator 30. Particularly, in the case of the present embodiment, the actuator 30 is inserted into a groove 47 formed in a lower surface of the vibration transferring part 40 to thereby be coupled to the vibration transferring part 40. Therefore, the vibration transferring part 40 having the actuator 30 coupled thereto is formed entirely in a single plate shape and is interposed between the display panel 20 and the support plate 60.

In the haptic driving assembly 50 configured as described above, the vibrations generated in the actuator 30 vibrate the medium part 42 of the vibration transferring part 40. That is, the display panel 20 disposed on an upper portion of the vibration transferring part 40 vibrates due to the medium part 42.

In the process, the vibrations generated in the actuator 30 vibrate the entire liquid phase medium part 42 while being transferred to the vibration transferring part 40. Therefore, the entire vibration transferring part 40 vibrates at a uniform strength without allowing the strength of the vibrations to be concentrated on any one point (for example, a point adjacent to the actuator).

In addition, the uniform vibrations generated in the vibration transferring part are transferred to the display panel 20 disposed to contact the upper surface of the vibration transferring part 40. As a result, the display panel 20 provides entirely uniform vibrational sensitivity without allowing the vibrations to be concentrated on a portion thereof.

The support plate 60 is formed to have a flat plate shape, and has the above-mentioned vibration transferring part 40 coupled to one surface, that is, an upper surface, thereof.

The vibration transferring part 40 according to the present embodiment may be fixedly coupled to the support plate 60 by an adhesive member 70.

The adhesive member 70 may be any member if it is a member having strong adhesion force so that the vibration transferring part 40 is firmly fixed to the support plate 60. As the adhesive member 70, a thermosetting adhesive capable of maintaining strength while having large adhesion force may be used, and more specifically, an epoxy resin adhesive may be used.

In addition, the mobile communications terminal 10 according to the present embodiment may have a buffering member 80 formed along the circumference of the support plate 60. The buffering member 80 may be formed of a rubber material, and keep vibrations generated in the support plate 60 from being directly transferred to the case 14.

In the case in which the mobile communications terminal 10 includes the buffering member 80 as described above, most of the vibrations generated in the haptic driving assembly 50 are transferred to the display panel 20 rather than the case 14, whereby the user only feels vibratory feedback in the display panel 20. Therefore, the user may more accurately feel a haptic sensation for touch input.

In the mobile communications terminal 100 according to the present embodiment configured as described above, an ultrasonic wave generated by the vibrations of the actuator 30 vibrates the entire medium part 42 of the vibration transferring part 40, such that the generated vibratory force is transferred to the display panel 20.

Therefore, the vibration generated in the actuator 30 is uniformly transferred to the display panel 20 by the vibration transferring part 40 without being concentrated on any one point, such that more accurate feedback for the touch input may be provided to the user.

The mobile communications terminal according to the exemplary embodiment of the present invention configured as described above is not limited to the above-mentioned exemplary embodiments, but various applications may be made.

FIG. 4, which is a partial cross-sectional view of a mobile communications terminal according to another exemplary embodiment of the present invention, shows a portion corresponding to FIG. 3. Referring to FIG. 4, a haptic driving assembly 50′ of a mobile communications terminal 200 according to the present embodiment is configured to have a structure in which an actuator 30′ is disposed in an inner portion of a vibration transferring part 40′, unlike a structure of the haptic driving assembly 50 (See FIG. 1) according to the above-mentioned exemplary embodiment in which the actuator 30 is coupled to the groove 47 formed on the lower surface of the vibration transferring part 40.

That is, the actuator 30 is inserted into the inner portion of the vibration transferring part 40′ to thereby be attached to an inner surface of the protective cover 45. Therefore, an upper surface and sides of the actuator 30 directly contact the medium part 42 of the vibration transferring part 40′.

Here, the actuator 30′ according to the present embodiment may include a coating layer 32 formed by coating a waterproof agent or a water repellent agent on an outer surface thereof. In this case, the outer surface of the actuator 30 directly contacts the liquid phase medium part 42, whereby a problem such as corrosion of the actuator 30, or the like, may be prevented.

With the mobile communications terminal according to the exemplary embodiments of the present invention configured as described above, the actuator serves as an ultrasonic wave vibrator and radiates an ultrasonic wave through vibrations, and the entire medium part of a liquid phase vibration transferring part uniformly vibrates due to the ultrasonic wave.

Therefore, the vibrations are entirely uniformly transferred to the display panel that contacts the vibration transferring part without being partially concentrated therein. As a result, more uniform and accurate feedback for touch input may be provided to the user, as compared to the case according to the related art.

As set forth above, with a haptic driving assembly and an electronic device using the same according to exemplary embodiments of the present invention, an actuator serves as an ultrasonic wave vibrator and radiates an ultrasonic wave through vibrations, and the entire medium part of a liquid phase vibration transferring part uniformly vibrates due to the ultrasonic wave.

Therefore, the vibrations are entirely uniformly transferred to a display panel that contacts the vibration transferring part without being partially concentrated therein.

As a result, more uniform and accurate feedback for touch input may be provided to a user, as compared to the case according to the related art.

Further, most vibrations generated in the haptic driving assembly are directly transferred to the display panel rather than a case, whereby the user may more accurately feel the haptic sensation for touch input.

Meanwhile, the haptic driving assembly and the electronic device using the same according to the exemplary embodiments of the present invention as described above are not limited to the aforementioned embodiments, but various applications may be made. For example, although the above-mentioned exemplary embodiments describe a case in which two actuators are used, the present invention is not limited thereto. Various numbers of actuators may be disposed to have various shapes as needed.

In addition, although the above-mentioned exemplary embodiments describe a case in which the actuator is fixedly coupled to the support plate in a shape in which it is inserted into the inner portion of the vibration transferring part, a separate groove may be formed in the support plate, and at least a portion of the actuator may be inserted into the groove, as necessary. In this case, a portion of the actuator may be inserted into the support plate, and a remaining portion thereof may be inserted into the vibration transferring part.

Further, although the above-mentioned exemplary embodiments describe the mobile communications terminal by way of example, the present invention is not limited thereto but may be applied to various devices if they are electronic devices providing the haptic feedback.

While the present invention has been shown and described in connection with the exemplary embodiments, it will be apparent to those skilled in the art that modifications and variations can be made without departing from the spirit and scope of the invention as defined by the appended claims.

What is claimed is:

1. A haptic driving assembly comprising:
at least one actuator; and
a vibration transferring part disposed to contact at least one surface of the actuator and transferring vibrations generated in the actuator to the outside through a liquid phase medium.

2. The haptic driving assembly of claim 1, wherein the vibration transferring part includes:
a medium part formed of the liquid phase medium; and
a protective cover enclosing an outer portion of the medium part and protecting the medium part.

3. The haptic driving assembly of claim 2, wherein the medium part is formed of a liquid material having a specific gravity greater than that of water.

4. The haptic driving assembly of claim 2, wherein the protective cover is formed of a film material having flexibility.

5. The haptic driving assembly of claim 2, wherein the actuator is attached to an inner surface of the protective cover, such that all surfaces thereof except for a surface attached to the inner surface of the protective cover directly contact the medium part.

6. The haptic driving assembly of claim 1, wherein the vibration transferring part includes at least one groove having the actuator inserted thereinto and contacting thereto.

7. The haptic driving assembly of claim 1, wherein the actuator is a piezo actuator having a bar shape.

8. The haptic driving assembly of claim 1, wherein the actuator generates an ultrasonic wave through the vibrations to thereby transfer the ultrasonic wave to the vibration transferring part.

9. The haptic driving assembly of claim 8 wherein the vibration transferring part has the medium part vibrated by the ultrasonic wave transferred from the actuator and transfers the vibrations to the outside.

10. An electronic device comprising:
the haptic driving assembly of claim 1; and
a display panel disposed to contact an outer portion of the vibration transferring part.

11. The electronic device of claim 10, wherein the display panel includes:
an image displaying unit displaying an image; and
a touch panel attached to an upper surface of the image displaying unit to thereby sense touch input from the outside.

12. The electronic device of claim 10, further comprising a case receiving the haptic driving assembly and the display panel therein.

13. The electronic device of claim 12, further comprising a buffering member fixedly coupled to a circumference of the support plate to thereby keep vibrations generated in the haptic driving assembly from being transferred to the case.

14. The electronic device of claim 10, further comprising a support plate having the haptic driving assembly disposed between the support plate and the display panel to thereby support the haptic driving assembly.
